(19) United States
(12) Patent Application Publication
(10) Pub. No.: US 2025/0085246 A1
(43) Pub. Date: Mar. 13, 2025

(54) DETECTION APPARATUS AND DETECTION METHOD

(71) Applicant: TERAPARK TECHNOLOGIES (NANJING) CO., LTD., Nanjing (CN)

(72) Inventor: Yan Zhao, Nanjing (CN)

(21) Appl. No.: 18/956,072

(22) Filed: Nov. 22, 2024

Related U.S. Application Data
(63) Continuation-in-part of application No. PCT/CN2023/096240, filed on May 25, 2023.

(30) Foreign Application Priority Data
May 25, 2022 (CN) 202210577235.1

(51) Int. Cl. G01N 27/04

(52) U.S. Cl. CPC G01N 27/041

(57) ABSTRACT

Disclosed are a detection apparatus and a detection method, and the detection apparatus includes: a transmitting module, configured to transmit a measurement electromagnetic wave to a surface of a side of a to-be-detected material; and a receiving and processing module, configured to receive a first electromagnetic wave and a second electromagnetic wave, and obtain, based on the first electromagnetic wave and the second electromagnetic wave, an electrical characteristic parameter of the surface and/or a body of the to-be-detected material that are irradiated by the measurement electromagnetic wave, where the first electromagnetic wave includes the measurement electromagnetic wave reflected from the surface of the to-be-detected material, and the second electromagnetic wave includes the measurement electromagnetic wave transmitting through the to-be-detected material.

### CROSS-REFERENCE TO RELATED APPLICATIONS

The present application is a continuation-In-Part application of International Application No. PCT/CN2023/096240 filed on May 25, 2023, which claims priority to Chinese Patent Application No. 202210577235.1 filed on May 25, 2022. Both applications are incorporated herein by reference in their entireties.

### TECHNICAL FIELD

The present disclosure relates to the field of characteristic detection technologies, and in particular, to a detection apparatus and a detection method.

### BACKGROUND

In a production process, detections of electrical characteristic parameters such as a resistivity, a conductivity, a permittivity and the like of the material are often involved, and the parameters may reflect a quality of the material and provide a reference basis for subsequent use, and are of great significance.

In a conventional technology, a contact measurement is generally used. For example, a resistance is detected by using a four-probe resistance detecting method, that is, four probes are required to be in contact with a material or a product. However, when the foregoing method is used to detect a resistance of a material, since the probes need to be in contact with the material, the material or the product may be damaged to some extent in the measurement process, and a measurement speed is low. Therefore, it is necessary to provide a high-speed and nondestructive detection method.

### SUMMARY

In view of this, embodiments of the present disclosure provide a detection apparatus and a detection method, so as to perform a nondestructive detection on a to-be-detected material.

In a first aspect, embodiments of the present disclosure provide a detection apparatus, including: a transmitting module configured to transmit a measurement electromagnetic wave to a surface of a side of a to-be-detected material; and a receiving and processing module configured to receive a first electromagnetic wave and a second electromagnetic wave, and obtain, based on the first electromagnetic wave and the second electromagnetic wave, an electrical characteristic parameter of the surface and/or a body of to-be-detected material that are irradiated by the measurement electromagnetic wave, where the first electromagnetic wave includes the measurement electromagnetic wave reflected from the surface of the to-be-detected material, and the second electromagnetic wave includes the measurement electromagnetic wave transmitting through the to-be-detected material.

In an example, the to-be-detected material includes at least one doped surface of the to-be-detected material; the transmitting module is configured to transmit the measurement electromagnetic wave to the doped surface of the to-be-detected material; the first electromagnetic wave includes at least one reflected electromagnetic wave, the second electromagnetic wave includes at least one transmitted electromagnetic wave, the reflected electromagnetic wave includes the measurement electromagnetic wave reflected from the doped surface of the to-be-detected material, and the transmitted electromagnetic wave includes the measurement electromagnetic wave transmitting through the doped surface of the to-be-detected material; and the receiving and processing module is configured to receive the reflected electromagnetic wave and the transmitted electromagnetic wave, and obtain, based on the reflected electromagnetic wave, an electrical characteristic parameter of the doped surface of the to-be-detected material, and obtain, based on the transmitted electromagnetic wave and the electrical characteristic parameter of the doped surface of the to-be-detected material, the electrical characteristic parameter of the body of the to-be-detected material.

In an example, the receiving and processing module is configured to obtain an electrical characteristic image of the doped surface of the to-be-detected material based on the reflected electromagnetic wave, and calculate the electrical characteristic parameter of the doped surface of the to-be-detected material based on a pixel grayscale value of the electrical characteristic image; and the receiving and processing module is further configured to calculate an intermediate parameter based on the transmitted electromagnetic wave, and use a difference between the intermediate parameter and the electrical characteristic parameter of the doped surface of the to-be-detected material as the electrical characteristic parameter of the body of the to-be-detected material.

In an example, the to-be-detected material includes a first doped surface and a second doped surface, and the first doped surface and the second doped surface are two opposite surfaces of the to-be-detected material; the first electromagnetic wave includes a first reflected electromagnetic wave and a second reflected electromagnetic wave; the first reflected electromagnetic wave is the measurement electromagnetic wave reflected from the first doped surface, and the second reflected electromagnetic wave is the measurement electromagnetic wave reflected from the second doped surface; and the receiving and processing module is configured to obtain an electrical characteristic parameter of the first doped surface based on the first reflected electromagnetic wave, and obtain an electrical characteristic parameter of the second doped surface based on the second reflected electromagnetic wave, and obtain the electrical characteristic parameter of the body of the to-be-detected material based on the transmitted electromagnetic wave, the electrical characteristic parameter of the first doped surface and the electrical characteristic parameter of the second doped surface.

In an example, the detection apparatus further includes: a first optical module, where the first optical module is configured to adjust an emission angle, a reflection angle and a transmission angle of the measurement electromagnetic wave.

In an example, the transmitting module includes a plurality of transmitters arranged in an array; and the receiving and processing module includes a plurality of receivers arranged in an array.

In an example, the plurality of receivers are arranged in an M×N array, and the plurality of transmitters are arranged in a X×Y array, M, N, X and Y are integers greater than or equal to 1, and M×N is equal to X×Y, or M×N is not equal to X×Y.

In an example, the detection apparatus further includes: a second optical module, where the second optical module is configured to focus the measurement electromagnetic wave, the first electromagnetic wave and the second electromagnetic wave.

In an example, the detection apparatus further includes: an excitation light source, where the excitation light source is configured to focus on a measurement region of the to-be-detected material, and excite the to-be-detected material to detect the electrical characteristic parameter of the body of the to-be-detected material.

In an example, the electrical characteristic parameter of the body of the to-be-detected material includes a carrier lifetime, and the excitation light source is configured to excite a carrier of the to-be-detected material to detect the carrier lifetime.

In an example, the transmitting module includes a first transmitter, the receiving and processing module includes a first receiver and a second receiver, the first receiver is configured to receive the first electromagnetic wave, and the second receiver is configured to receive the second electromagnetic wave, and the receiving and processing module is configured to obtain the electrical characteristic parameter of the body of the to-be-detected material based on the first electromagnetic wave and the second electromagnetic wave, and obtain a type of the to-be-detected material based on the electrical characteristic parameter of the body of the to-be-detected material.

In an example, the transmitting module includes a transmitter, the receiving and processing module includes a receiver and a processor, and the receiver is connected to the processor, or the processor is integrated into the receiver.

In a second aspect, the embodiments of the present disclosure provide a detection apparatus, including: an electromagnetic wave transceiver module, where the electromagnetic wave transceiver module is configured to transmit a measurement electromagnetic wave to a first doped surface and a second doped surface of a to-be-detected material, and receive a third electromagnetic wave and a fourth electromagnetic wave, the third electromagnetic wave includes the measurement electromagnetic wave reflected from the first doped surface and the second doped surface of the to-be-detected material, and the fourth electromagnetic wave includes the measurement electromagnetic wave transmitting through the to-be-detected material; and the electromagnetic wave transceiver module is further configured to obtain electrical characteristic parameters of the first doped surface and the second doped surface of the to-be-detected material and an electrical characteristic parameter of the body of the to-be-detected material based on the third electromagnetic wave and the fourth electromagnetic wave.

In an example, there are at least two electromagnetic wave transceiver modules, and the at least two electromagnetic wave transceiver modules operate in a time division mode, or the at least two electromagnetic wave transceiver modules operate in a frequency division mode; in a case of the time division mode, the at least two electromagnetic wave transceiver modules transmit and receive the measurement electromagnetic waves at different times; in the case of the frequency division mode, the at least two electromagnetic wave transceiver modules transmit and receive the measurement electromagnetic waves of different frequencies.

In an example, the electromagnetic wave transceiver module includes a transceiver, the transceiver includes a transmitter, a receiver and a processor, and the receiver is connected to the processor, or the processor is integrated into the receiver.

In a third aspect, the embodiments of the present disclosure provide a detection method, including: transmitting a measurement electromagnetic wave to a surface of a side of a to-be-detected material; and receiving a first electromagnetic wave and a second electromagnetic wave, and obtaining, based on the first electromagnetic wave and the second electromagnetic wave, an electrical characteristic parameter of the surface and/or a body of the to-be-detected material that are irradiated by the measurement electromagnetic wave, where the first electromagnetic wave includes the measurement electromagnetic wave reflected by the surface of the to-be-detected material, and the second electromagnetic wave includes the measurement electromagnetic wave transmitting through the to-be-detected material.

In an example, the to-be-detected material includes at least one doped surface of the to-be-detected material; the transmitting a measurement electromagnetic wave to a surface of a side of a to-be-detected material, includes: transmitting the measurement electromagnetic wave to the doped surface of the to-be-detected material; the first electromagnetic wave includes at least one reflected electromagnetic wave, the second electromagnetic wave includes at least one transmitted electromagnetic wave, the reflected electromagnetic wave includes a first part of the measurement electromagnetic wave reflected from the doped surface of the to-be-detected material, and the transmitted electromagnetic wave includes a second part of the measurement electromagnetic wave transmitting through the doped surface of the to-be-detected material; and the receiving a first electromagnetic wave and a second electromagnetic wave, and obtaining, based on the first electromagnetic wave and the second electromagnetic wave, an electrical characteristic parameter of the surface and/or a body of the to-be-detected material that are irradiated by the measurement electromagnetic wave, includes: receiving the reflected electromagnetic wave and the transmitted electromagnetic wave, and obtaining, based on the reflected electromagnetic wave, an electrical characteristic parameter of the doped surface of the to-be-detected material, and obtaining, based on the transmitted electromagnetic wave and the electrical characteristic parameter of the doped surface of the to-be-detected material, the electrical characteristic parameter of the body of the to-be-detected material.

In an example, the method further includes: obtaining an electrical characteristic image of the doped surface of the to-be-detected material based on the reflected electromagnetic wave, and calculating the electrical characteristic parameter of the doped surface of the to-be-detected material based on a pixel grayscale value of the electrical characteristic image; and calculating an intermediate parameter based on the transmitted electromagnetic wave, and using a difference between the intermediate parameter and the electrical characteristic parameter of the doped surface of the to-be-detected material as the electrical characteristic parameter of the body of the to-be-detected material.

In an example, the transmitting a measurement electromagnetic wave to a surface of a side of a to-be-detected material, includes: transmitting, by a transmitting module, the measurement electromagnetic wave to the surface of a side of the to-be-detected material, where the transmitting module includes a transmitter.

In an example, the receiving a first electromagnetic wave and a second electromagnetic wave, and obtaining, based on the first electromagnetic wave and the second electromagnetic wave, an electrical characteristic parameter of the surface and/or a body of the to-be-detected material that are irradiated by the measurement electromagnetic wave, includes: receiving, by a receiving and processing module, the first electromagnetic wave and the second electromagnetic wave, and obtaining, by the receiving and processing module based on the first electromagnetic wave and the second electromagnetic wave, the electrical characteristic parameter of each of the surface and the body of the to-be-detected material that are irradiated by the measurement electromagnetic wave, where the receiving and processing module includes a receiver and a processor, and the receiver is connected to the processor, or the processor is integrated into the receiver.

According to the detection apparatus provided by the embodiments of the present disclosure, the detection apparatus includes a transmitting module and a receiving and processing module, the transmitting module is configured to transmit a measurement electromagnetic wave to a surface of a side of a to-be-detected material; and the receiving and processing module is configured to receive a first electromagnetic wave and a second electromagnetic wave, and obtain, based on the first electromagnetic wave and the second electromagnetic wave, an electrical characteristic parameter of the surface and/or a body of the to-be-detected material that are irradiated by the measurement electromagnetic wave, where the first electromagnetic wave includes the measurement electromagnetic wave reflected from the surface of the to-be-detected material, and the second electromagnetic wave includes the measurement electromagnetic wave transmitting through the to-be-detected material. In this way, by transmitting the electromagnetic wave to the to-be-detected material, and by receiving the reflected and transmitted electromagnetic wave, the electrical characteristic parameter of the surface of the to-be-detected material and the electrical characteristic parameter of the body of the to-be-detected material may be obtained according to a receiving result of the electromagnetic wave and an electromagnetic wave attenuation principle, so that a nondestructive detection is realized, and the electrical characteristic parameter of the surface of the to-be-detected material and the electrical characteristic parameter of the body of the to-be-detected material may be detected by transmitting an electromagnetic wave once, thereby greatly improving a detection effect.

### BRIEF DESCRIPTION OF THE DRAWINGS

By describing the embodiments of the present disclosure in more detail with reference to accompanying drawings, the foregoing and other objectives, features and advantages of the present disclosure will become more apparent. The accompanying drawings are used to provide a further understanding of the embodiments of the present disclosure, constitute a part of this specification, and are used together with the embodiments of the present disclosure to explain the present disclosure, which does not constitute a limitation to the present disclosure. In the accompanying drawings, the same reference numerals typically represent the same component or step.

FIG. 1 is a schematic structural diagram of a transmitter and a receiver of a detection apparatus according to an embodiment of the present disclosure.

FIG. 2 is a waveform diagram used by a detection apparatus according to an embodiment of the present disclosure.

FIG. 3 is a schematic diagram of detecting only an electrical characteristic of a body of a to-be-detected material by a detection apparatus according to an embodiment of the present disclosure.

FIG. 4 is a schematic diagram of detecting only an electrical characteristic of a surface of a to-be-detected material by a detection apparatus according to an embodiment of the present disclosure.

FIG. 5 is a schematic diagram of detecting an electrical characteristic parameter of a doped surface of a to-be-detected material and an electrical characteristic parameter of a body of the to-be-detected material by a detection apparatus according to an embodiment of the present disclosure.

FIG. 6 is a schematic diagram of detecting an electrical characteristic parameter of a two-sided doped surface of a to-be-detected material by a detection apparatus according to an embodiment of the present disclosure.

FIG. 7 is a schematic diagram of detecting an electrical characteristic parameter of a two-sided doped surface of a to-be-detected material by a detection apparatus according to another embodiment of the present disclosure.

FIG. 8 is a schematic diagram of a detection apparatus that is used for detecting a doped surface of a to-be-detected material and includes a first optical module according to an embodiment of the present disclosure.

FIG. 9 is a schematic diagram of a detection apparatus that is used for detecting a two-sided doped surface and includes a first optical module according to an embodiment of the present disclosure.

FIG. 10a is a schematic structural diagram of a transceiver integrated detection module according to an embodiment of the present disclosure.

FIG. 10b is a schematic structural diagram of a transceiver integrated detection module according to another embodiment of the present disclosure.

FIG. 11 is a schematic structural diagram of a transmission detection apparatus including a second optical module according to an embodiment of the present disclosure.

FIG. 12 is a schematic structural diagram of a reflection detection apparatus including a second optical module according to an embodiment of the present disclosure.

FIG. 13 is a schematic structural diagram of a detection apparatus combined with transmission and reflection and including a second optical module according to an embodiment of the present disclosure.

FIG. 14 is a schematic structural diagram of a detection apparatus including a second optical module on one side according to an embodiment of the present disclosure.

FIG. 15 is a schematic diagram of images of a to-be-detected material respectively in an optical vision and a detection apparatus according to the present disclosure.

FIG. 16 is a schematic diagram of a line array detection apparatus according to an embodiment of the present disclosure.

FIG. 17 is a schematic diagram of a line array detection apparatus combined with a transmission mirror according to an embodiment of the present disclosure.

FIG. 18 is a schematic diagram of a line array detection apparatus for receiving an electromagnetic wave by a receiver array chip according to an embodiment of the present disclosure.

FIG. 19 is an installation schematic diagram of a line array detection apparatus according to an embodiment of the present disclosure.

FIG. 20 is an installation schematic diagram of a three-point detection apparatus according to an embodiment of the present disclosure.

FIG. 21 is an installation schematic diagram of a single-point detection apparatus according to an embodiment of the present disclosure.

FIG. 22 is a schematic diagram of a surface array detection apparatus according to an embodiment of the present disclosure.

FIG. 23 is a schematic flowchart of a detection method according to an embodiment of the present disclosure.

### DETAILED DESCRIPTION OF THE EMBODIMENTS

The following clearly describes technical solutions in embodiments of the present disclosure with reference to accompanying drawings in the embodiments of the present disclosure. Obviously, the described embodiments are a part of the embodiments of the present disclosure, rather than all the embodiments. Based on the embodiments of the present disclosure, all other embodiments obtained by those of ordinary skill in the art without creative work fall within the protection scope of the present disclosure.

### Overview

With the continuous development of material science, various emerging materials and products constantly appear, including photovoltaic silicon wafers, semiconductor silicon wafers, high-frequency plates, ceramic substrates, insulating materials, graphene, polymer materials and other non-metallic materials. In practical applications, in order to use the foregoing materials or products, a characteristic detection needs to be performed on the foregoing materials or products, for example, a resistivity, a conductivity, a permittivity, a thickness, a weight, a purity and a size of distributed particles and other parameters, and the parameters may directly reflect quality and performance of the materials or products, thereby providing reference for use of the materials or the products.

A resistivity detection of a photovoltaic silicon wafer is used as an example. In the conventional technology, a four-probe method is generally adopted in offline detection to detect an electrical characteristic of the material, that is, an electrical characteristic parameter of a to-be-detected material is obtained through the contact between a probe and a sample of the to-be-detected material, and the change of the characteristic such as a current voltage. However, when the electrical characteristic of the material is detected by using the four-probe method, the probe needs to be in contact with the to-be-detected material, which belongs to a contact detection, and thus the material is easily damaged and the detection speed is slow. Therefore, only the random inspection of samples can be carried out, full detection cannot be performed on all to-be-detected materials, and the electrical characteristics of each to-be-detected material cannot be accurately detected. A full detection method is also used on a production line, for example, a vortex sensor is used to generate a low frequency alternating current electromagnetic field and sense an induced current on a silicon wafer, so as to indirectly detect a resistivity. A detection speed of this type of method is relatively fast, but a detection area is relatively large, and an average resistivity in a few centimeters can be roughly detected. Due to a large sensing region, this technology cannot accurately present the two-dimensional distribution of a resistivity of a silicon wafer.

The present disclosure provides a method and an apparatus for detecting the resistivity two-dimensional distribution of a silicon wafer in a high speed, nondestructive and refined manner. In a propagation process, materials with different characteristics have different impacts on attenuation of an electromagnetic wave. For example, for the resistivity, the higher the resistivity of the material, the weaker the reflection, and the more serious attenuation of the reflected electromagnetic wave. During a transmission process, the greater the resistivity, the less the attenuation of the transmitted electromagnetic wave. Therefore, an electrical characteristic of a to-be-detected material may be obtained according to an electromagnetic wave attenuation principle by irradiating an electromagnetic wave to the to-be-detected material, to collect a reflected or transmitted electromagnetic wave passing the to-be-detected material, thereby implementing nondestructive detection. In addition, an electrical characteristic parameter of a surface of the to-be-detected material and an electrical characteristic parameter of a body of the to-be-detected material may be obtained according to the electromagnetic wave attenuation principle by collecting both an electromagnetic wave reflected by the to-be-detected material and an electromagnetic wave transmitting through the to-be-detected material. The electrical characteristic parameter of the surface of the to-be-detected material and the electrical characteristic parameter of the body of the to-be-detected material can be detected at one time, thereby greatly improving detection efficiency.

After basic principles of the present disclosure are described, following specifically describes various non-limiting embodiments of the present disclosure with reference to accompanying drawings.

### Example Apparatus

In an embodiment of the present disclosure, a detection apparatus includes a transmitting module and a receiving and processing module, and the detection apparatus is configured to detect an electrical characteristic parameter of a surface of a to-be-detected material and an electrical characteristic parameter of a body of the to-be-detected material (substrate). The transmitting module is configured to transmit a measurement electromagnetic wave to the surface of a side of the to-be-detected material; and the receiving and processing module is configured to: receive a first electromagnetic wave and a second electromagnetic wave, and obtain, based on the first electromagnetic wave and the second electromagnetic wave, the electrical characteristic parameter of the surface and/or a body of the to-be-detected material that are irradiated by the measurement electromagnetic wave, where the first electromagnetic wave includes the measurement electromagnetic wave reflected from the surface of the to-be-detected material, and the second electromagnetic wave includes the measurement electromagnetic wave transmitting through the to-be-detected material.

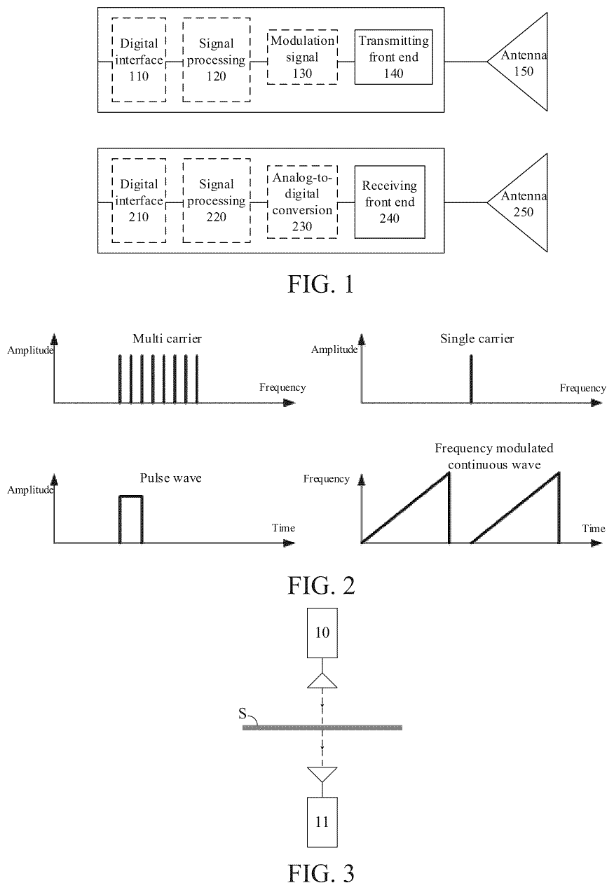

Specifically, the transmitting module may be a transmitter, namely, an electromagnetic wave transmitter. The receiving and processing module may be a receiver integrated to receive electromagnetic waves and data processing functions, namely, an electromagnetic wave receiver, or may be a separate receiver, namely, an electromagnetic wave receiver and a data processing module connected thereto. The data processing module may perform calculation based on data received by the electromagnetic wave receiver, to obtain the electrical characteristic parameter of the surface of the to-be-detected material and the electrical characteristic parameter of the body of the to-be-detected material. FIG. 1 is a schematic structural diagram of a transmitter and a receiver of a detection apparatus according to an embodiment of the present disclosure. The upper part of FIG. 1 is a schematic structural diagram of the transmitter, and the lower part of FIG. 1 is a schematic structural diagram of the receiver. As shown in FIG. 1, the transmitter includes a digital interface 110, a circuit of a signal processing 120, a circuit of a modulation signal 130, a transmitting front end 140 and an antenna 150, and the receiver includes a digital interface 210, a circuit of a signal processing 220, a circuit of an analog-to-digital conversion 230, a receiving front end 240, and an antenna 250, so as to separately implement functions of transmitting and receiving the electromagnetic waves.

The transmitter is disposed on a side of the to-be-detected material at a specific angle, and the transmitter is configured to transmit the measurement electromagnetic wave to a to-be-detected area on a surface of the side of the to-be-detected material, so that the measurement electromagnetic wave is irradiated to the to-be-detected area on the surface of the to-be-detected material at a specific irradiated angle. When the measurement electromagnetic wave reaches the to-be-detected area at the surface of the to-be-detected material, a part of the measurement electromagnetic wave is reflected from the surface of the to-be-detected material, and an original propagation path is changed. The reflected measurement electromagnetic wave is denoted as the first electromagnetic wave and is received by the receiver. The another part of the measurement electromagnetic wave passes through the to-be-detected area of the to-be-detected material and reaches the other side of the to-be-detected material, which is denoted as the second electromagnetic wave and is also received by a receiver.

It should be noted that, in a process of the measurement electromagnetic wave in reflection and transmission, degrees of attenuation are different depending on different electrical characteristics of the to-be-detected material. The resistivity is used as an example, for reflection, the greater the resistivity of the to-be-detected material, the stronger the attenuation, and the weaker the reflected first electromagnetic wave; the greater the resistivity, and the stronger the transmitted second electromagnetic wave. In addition, the degree of the attenuation of the first electromagnetic wave mainly depends on a characteristic of the surface of the to-be-detected material, and the degree of the attenuation of the second electromagnetic wave further depends on a characteristic of the body of the to-be-detected material. Therefore, in the embodiment of the present disclosure, the first electromagnetic wave and the second electromagnetic wave are received and processed by using a receiver. Based on the electromagnetic wave attenuation principle, the electrical characteristic parameter of the surface of the to-be-detected material and the electrical characteristic parameter of the body of the to-be-detected material may be separately obtained by means of analysis and calculation.

The detection apparatus provided in the present disclosure includes the transmitting module and the receiving and processing module. The transmitting module includes a transmitter, configured to transmit the measurement electromagnetic wave to the surface of a side of the to-be-detected material. The receiving and processing module includes a receiver with the data processing function, or includes a receiver and a processing module connected to the receiver, configured to receive the first electromagnetic wave reflected from the surface of the to-be-detected material and a second electromagnetic wave transmitting through the to-be-detected material. Based on the electromagnetic wave attenuation principle, the first electromagnetic wave and the second electromagnetic wave that are received, the electrical characteristic parameter of the surface of the to-be-detected material and the electrical characteristic parameter of the body of the to-be-detected material may be obtained, so that the nondestructive detection is realized. In addition, by transmitting the electromagnetic wave once, the electrical characteristic parameter of the surface of the to-be-detected material and the electrical characteristic parameter of the body of the to-be-detected material may be detected, thereby greatly improving detection efficiency.

In actual application, the transmitter used in the embodiment of the present disclosure includes, but is not limited to, a transmitter with any form of an oscillator, a frequency multiplier, or an up-conversion mixer and a short pulse generator (for example, a terahertz short pulse generator generated based on a photoexcitation source such as a quantum cascade laser or a free electron laser). The receiver includes, but is not limited to, a microbolometer, a golay receiver, a pyroelectric receiver, a Schottky diode receiver, a field effect transistor receiver, a bipolar transistor receiver, a high electron mobility transistor receiver, a superheterodyne or zero intermediate frequency coherent receiver.

In addition, in the present disclosure, the transmitter and the receiver may operate in a plurality of signal forms. FIG. 2 is a waveform diagram used by a detection apparatus according to an embodiment of the present disclosure. As shown in FIG. 2, in the embodiment of the present disclosure, the transmitter and the receiver may use a single carrier, a multi carrier, a frequency modulation continuous wave, or a pulse wave and so on.

In some specific implementation processes, the electromagnetic wave used for achieving measurement in the present disclosure may adopt a terahertz electromagnetic wave, the transmitter correspondingly used is a terahertz wave transmitter, and the receiver is a terahertz wave receiver. A broad definition range of a terahertz frequency band is from 0.1 THz (100 GHz) to 10 THz. The terahertz transmitter is used to transmit a measurement terahertz wave, and then the terahertz receiver is used to receive a terahertz wave, so as to complete the foregoing detection. Because the frequency of the terahertz wave is relatively high, a detection resolution may be greatly improved by using the terahertz electromagnetic wave, so that a minimum imaging point may be fine-grained to a millimeter level or even a submillimeter level, thereby implementing high-precision detection.

Certainly, in the embodiment of the present disclosure, the measurement electromagnetic wave may also be an electromagnetic wave of another frequency band. For example, a wave of a relatively low frequency band, including a millimeter wave, a microwave and a radio frequency band, may be used in the present disclosure, and a difference lies only in a size of an imaging resolution (namely, a minimum detection area). In actual application, according to an actual requirement and consideration of costs, an electromagnetic wave of a suitable waveband may be selected to complete detection.

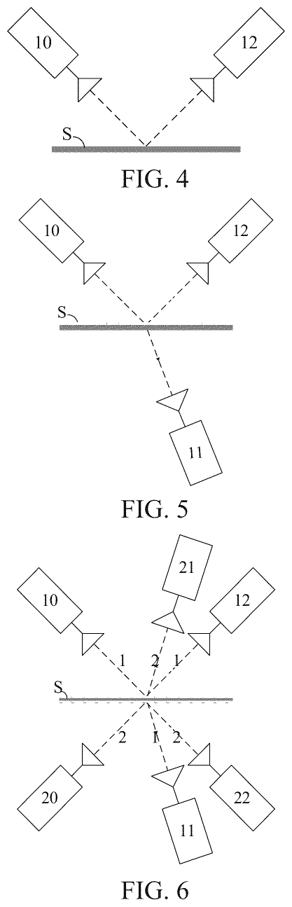

It should be noted that the detection apparatus provided in the present disclosure may alternatively detect only the electrical characteristic parameter of the body of the to-be-detected material or the electrical characteristic parameter of the surface of the to-be-detected material. FIG. 3 is a schematic diagram of detecting only an electrical characteristic of a body of a to-be-detected material by a detection apparatus according to an embodiment of the present disclosure. FIG. 4 is a schematic diagram of detecting only an electrical characteristic of a surface of a to-be-detected material by a detection apparatus according to an embodiment of the present disclosure. As shown in FIG. 3 and FIG. 4, for the detection of the electrical characteristic parameter of the body of the to-be-detected material, a transmission principle may be used, that is, a transmitter 10 is disposed on a side of a to-be-detected material S, such as a silicon wafer that is not doped on a surface, and a receiver 11 is disposed on the other side of the to-be-detected material S. The receiver 11 receives the electromagnetic wave transmitting through the to-be-detected material S, and then the electrical characteristic parameter of the to-be-detected material S is obtained according to the electromagnetic wave attenuation principle. For detection of the electrical characteristic parameter of the surface of the to-be-detected material S, in this case, the surface may be a silicon wafer surface or a surface with a silicon wafer doped, and a principle of reflection may be used, that is, a transmitter 10 and a receiver 12 may be disposed on a side of the to-be-detected material S, the receiver 12 receives the electromagnetic wave on the surface of the to-be-detected material S, and then the electrical characteristic parameter of the surface of the to-be-detected material S is obtained according to the electromagnetic wave attenuation principle.

In actual application, in order to enable the material to meet more requirements, doping is often performed on one surface or two surfaces of the material. After doping is performed on the surface plating layer of the to-be-detected material, the electrical characteristic parameter of the surface of the to-be-detected material and the electrical characteristic parameter of the body of the to-be-detected material are relatively different. In this case, the electrical characteristic parameter of the surface of the to-be-detected material and the electrical characteristic parameter of the body of the to-be-detected material need to be separately detected. Following uses the silicon wafer as an example to describe in detail a principle of the detection apparatus provided in the present disclosure. It should be noted that the detection apparatus provided in the present disclosure may alternatively be used to detect the electrical performance of a high-frequency material plate, a ceramic substrate, an insulation material, graphene, a polymer material, and another non-metal material.

In some embodiments of the present disclosure, the detection apparatus includes a transmitting module and at least two receiving and processing modules, the transmitting module includes a transmitter, and the receiving and processing module includes a receiver with a data processing function, or includes a receiver and a processing module connected to the receiver. The transmitter is configured to transmit the measurement electromagnetic wave to the doped surface of the to-be-detected material; the receiver is configured to receive a first electromagnetic wave that includes at least one reflected electromagnetic wave, and receive a second electromagnetic wave that includes at least one transmitted electromagnetic wave. The receiving and processing module obtains the electrical characteristic parameter of the doped surface of the to-be-detected material based on the reflected electromagnetic wave, and obtains the electrical characteristic parameter of the body of the to-be-detected material based on the transmitted electromagnetic wave and the electrical characteristic parameter of the doped surface of the to-be-detected material. FIG. 5 is a schematic diagram of detecting an electrical characteristic parameter of a doped surface of a to-be-detected material and an electrical characteristic parameter of the body of the to-be-detected material by a detection apparatus according to an embodiment of the present disclosure.

As shown in FIG. 5, FIG. 5 is an embodiment in which doping is performed on an upper surface of the to-be-detected material S. A transmitter 10 is disposed on the doped side of the to-be-detected material S such as a silicon wafer, a receiver 12 is disposed on a same side of the transmitter 10, and a receiver 11 is disposed on an opposite side of the transmitter. The electromagnetic wave transmitted by the transmitter 10, such as a terahertz wave, propagates at a specific angle to a to-be-detected area of the doped surface of the to-be-detected material S, such as a silicon wafer. A part of the terahertz wave is reflected from a surface of the to-be-detected area and received by the receiver 12, and a part of the terahertz wave is transmitted through the to-be-detected area and received by the receiver 11.

In an embodiment, the transmitting module includes a first transmitter, the receiving and processing module includes a first receiver and a second receiver, the first receiver is configured to receive the first electromagnetic wave, the second receiver is configured to receive the second electromagnetic wave, and the receiving and processing module is configured to obtain an electrical characteristic parameter of the body of the to-be-detected material based on the first electromagnetic wave and the second electromagnetic wave, and obtain a type of the to-be-detected material based on the electrical characteristic parameter of the body of the to-be-detected material.

It should be noted that a combination of three probes (for example, a combination of one transmitter and two receivers) may further be used to determine a type of a semiconductor material (that is, a P-type or an N-type), and the determination of the type is also determined based on the electrical characteristic parameter, for example, a specific type of the to-be-detected material may be determined according to a numerical range of the electrical characteristic parameter of the body of the to-be-detected material.

After the two receivers receive the reflected electromagnetic wave and the transmitted electromagnetic wave, the receiving and processing module obtains the electrical characteristic parameter of the doped surface of the to-be-detected material S according to a received result of the reflected electromagnetic wave and an electromagnetic wave attenuation principle, and then the receiving and processing module obtains the electrical characteristic parameter of the body of the to-be-detected material S according to the transmitted electromagnetic wave and the electromagnetic wave attenuation principle, and the electrical characteristic parameter of the doped surface of the to-be-detected material S. By respectively installing receivers on two sides of the to-be-detected material S, the electrical characteristic parameter of the doped surface of the to-be-detected material S and the electrical characteristic parameter of the body of the to-be-detected material S may be almost detected simultaneously. There is no need for the to-be-detected material S to stay, and no special sample stage is required. The detection apparatus may be directly installed on a production line of the to-be-detected material, and the each to-be-detected material S is detected at a high speed.

In addition, the detection apparatus further includes an excitation light source. The excitation light source is configured to focus on a measurement area of the to-be-detected material, and excite the to-be-detected material to detect the electrical characteristic parameter of the body of the to-be-detected material.

In an embodiment, the electrical characteristic parameter of the body of the to-be-detected material includes a carrier lifetime, and the excitation light source is configured to excite a carrier of the to-be-detected material to detect the carrier lifetime.

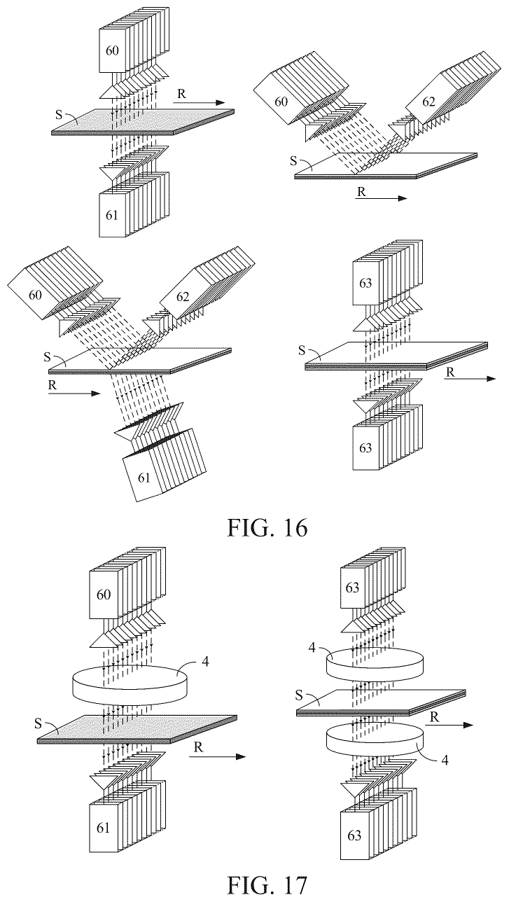

Specifically, the detection apparatus provided in the embodiment of the present disclosure may further include the excitation light source focused on the measurement area of the to-be-detected material (for example, a semiconductor material), and is configured to excite the carrier that may be electrically conductive in the semiconductor material. For example, referring to FIG. 5, the excitation light source is disposed in a lower left corner of FIG. 5. In addition, the excitation light source may also be disposed in any one of the embodiments described in FIG. 16 to FIG. 22, and the disposing of the excitation light source is not specifically limited in the embodiment of the present disclosure.

The excitation light source may be a visible light source, and the excitation light source is not specifically limited in the embodiment of the present disclosure. In the embodiment of the present disclosure, the excitation light source is added, to excite the carrier in a silicon wafer, so that a duration of existence of the carrier (namely, the carrier lifetime) can be detected by means of the terahertz technology in the embodiment of the present disclosure. It should be noted that, on the basis of the detection apparatus described in the foregoing embodiments, a scanning imaging system of the actual application may be implemented by adding a mechanical and electric slide rail and a housing, or the detection apparatus is installed on a conveyor belt to implement production line detection.

In some embodiments of the present disclosure, the receiving and processing module is configured to obtain an electrical characteristic image of the doped surface of the to-be-detected material based on the reflected electromagnetic wave, and calculate the electrical characteristic parameter of the doped surface of the to-be-detected material based on a pixel grayscale value of the electrical characteristic image. The receiving and processing module is further configured to calculate an intermediate parameter based on the transmitted electromagnetic wave, and use a difference between the intermediate parameter and the electrical characteristic parameter of the doped surface of the to-be-detected material as the electrical characteristic parameter of the body of the to-be-detected material.

Specifically, in the present disclosure, the electromagnetic wave such as a terahertz wave is used for incidence of the to-be-detected material, imaging is performed by means of a received reflected electromagnetic wave or a transmitted electromagnetic wave, and then an electrical characteristic parameter of the material is extracted and calculated based on a grayscale value of an imaged pixel. The electrical characteristic parameter represented by each pixel is an average electrical characteristic in which an actual physical area detected by each receiver is used as a minimum observation window. For example, in a case of 300 GHz, each pixel about 2×2 square millimeters, and an electrical characteristic parameter value extracted by the pixel is an average value within the area.

In some specific implementation processes, first imaging is performed by using the receiving result of the reflected electromagnetic wave, and the electrical characteristic parameter of the doped surface of the detection area is obtained by using the foregoing method. Because the transmission electromagnetic wave transmits through the doped surface of the to-be-detected material while transmitting through the body of the to-be-detected material, during calculation of the electrical characteristic parameter of the body of the to-be-detected material, firstly, imaging may be performed according to the transmission electromagnetic wave to obtain a mixed characteristic of the doped surface and the body, that is, the intermediate parameter, and then impact of an imaging parameter of the surface is removed to obtain the electrical characteristic parameter of the body of the to-be-detected material.

On the basis of the foregoing embodiments, in some embodiments, the to-be-detected material may alternatively be a material doped on two surfaces of the body, the to-be-detected material includes a first doped surface and a second doped surface, and the first doped surface and the second doped surface are two opposite surfaces of the to-be-detected material. The first electromagnetic wave includes a first reflected electromagnetic wave and a second reflected electromagnetic wave. The first reflected electromagnetic wave is the measurement electromagnetic wave reflected from the first doped surface, and the second reflected electromagnetic wave is a measurement electromagnetic wave reflected from the second doped surface. The receiving and processing module is specifically configured to obtain an electrical characteristic parameter of the first doped surface based on the first reflected electromagnetic wave, and obtain an electrical characteristic parameter of the second doped surface based on the second reflected electromagnetic wave, and obtain the electrical characteristic parameter of the body of the to-be-detected material based on the transmitted electromagnetic wave, the electrical characteristic parameter of the first doped surface and the electrical characteristic parameter of the second doped surface.

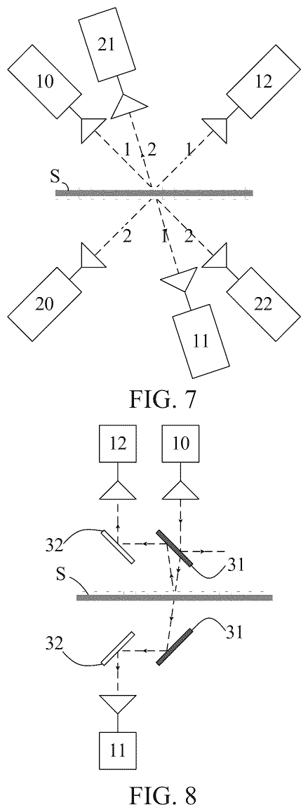

FIG. 6 is a schematic diagram of detecting electrical characteristic parameter of a two-sided doped surface of a to-be-detected material by a detection apparatus according to an embodiment of the present disclosure. FIG. 7 is a schematic diagram of detecting electrical characteristic parameter of a two-sided doped surface of a to-be-detected material by a detection apparatus according to an embodiment of the present disclosure.

As shown in FIG. 6 and FIG. 7, for the to-be-detected material S doped on two sides, such as a silicon wafer, that is, when a top surface and a bottom surface of the to-be-detected material are both doped, it only needs to add a set of transmitting apparatus and receiving apparatus on the basis of the foregoing embodiments to respectively measure the two opposite doped surfaces. For the first doped surface (such as the doped surface located on an upper layer of the to-be-detected material in FIG. 6), the first measurement electromagnetic wave may be transmitted by a transmitter 10, the first reflected electromagnetic wave reflected by the first doped surface is received by a receiver 12, and the transmitted electromagnetic wave is received by a receiver 11 on the other side. A second measurement electromagnetic wave is transmitted by a transmitter 20, the second electromagnetic wave reflected by the second doped surface is received by a receiver 22, and the transmitted electromagnetic wave is received by a receiver 21 on the other side.

Then, according to the method in the foregoing embodiment, the electrical characteristic parameter of the first doped surface of the to-be-detected material S is obtained based on the first reflected electromagnetic wave, and the electrical characteristic parameter of the second doped surface of the to-be-detected material S is obtained based on the second reflected electromagnetic wave. Finally, the electrical characteristic parameter of the body of the to-be-detected material S may be obtained according to the transmitted electromagnetic wave and the electrical characteristic parameters of the first doped surface and the second doped surface. Based on combination of two sets of transmitters and receivers, the electrical characteristic parameters of the two doped surfaces of the to-be-detected material S and the electrical characteristic parameter of the body of the to-be-detected material S may be detected simultaneously, thereby greatly improving detection efficiency.

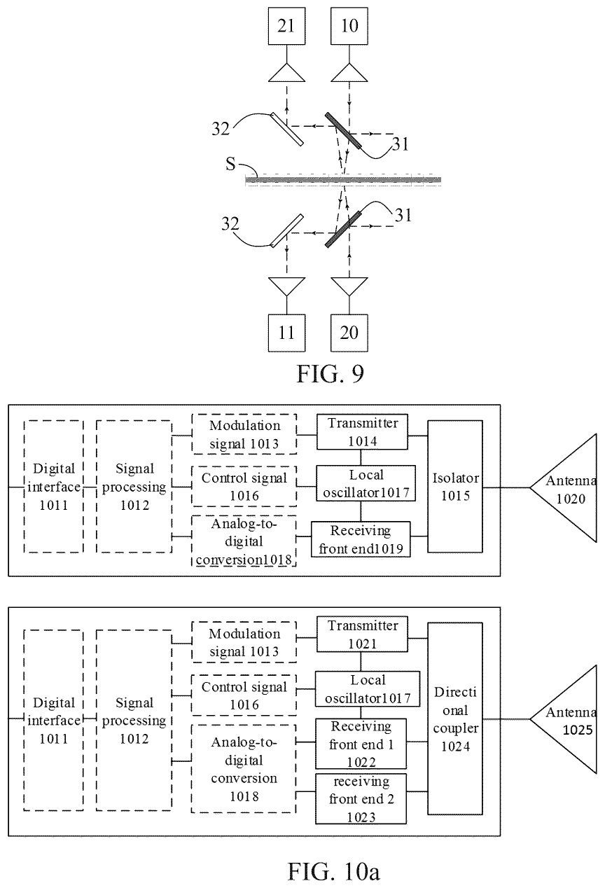

In actual application, when the doped surface of the to-be-detected material is bent, energies of a reflected wave and a transmitted wave detected by each receiver is weakened, and a detection effect is reduced. Based on this, in some other embodiments of the present disclosure, an emission angle, a reflection angle and a transmission angle of the measurement electromagnetic wave may be further adjusted by adding a first optical module. FIG. 8 is a schematic diagram of a detection apparatus that is used for detecting a doped surface of a to-be-detected material and includes a first optical module according to an embodiment of the present disclosure. FIG. 9 is a schematic diagram of a detection apparatus that is used for detecting a two-sided doped surfaces and includes a first optical module according to an embodiment of the present disclosure. As shown in FIG. 8 and FIG. 9, the first optical module is configured to adjust an emission angle, a reflection angle, and a transmission angle of the measurement electromagnetic wave.

Specifically, the first optical module may include a beam splitter 31 and a plane mirror 32. FIG. 8 is a structure of the first optical module of the to-be-detected material with a single side doped. FIG. 9 is a structure of a first optical module of the to-be-detected material with two sides doped. As shown in FIG. 8, the measurement electromagnetic wave emitted by a transmitter 10 is reflected and transmitted by the multi-pass beam splitter 31 to adjust the angle at incidence to the to-be-detected material S, so that a path of the measurement electromagnetic wave may be substantially perpendicular to the to-be-detected material S, and a propagation path of the reflected electromagnetic wave and a propagation path of the transmitted electromagnetic wave may be adjusted by using the beam splitter 31 and the plane mirror 32, so that the receiver 11 and the receiver 12 may vertically receive the transmitted electromagnetic wave or the reflected electromagnetic wave. In this way, not only a position of the transmitter and a position of the receiver may be randomly changed according to a working environment, but also installation difficulty is reduced, and a signal strength received is less affected by a bend of a surface of a silicon wafer.

Further, when the to-be-detected material S is two-sided doped, based on the foregoing theory, the propagation path of the electromagnetic wave is adjusted by using the beam splitter 31 and the plane mirror 32, so that the receiver that originally receives only the transmitted electromagnetic wave also receives, on the basis of receiving the transmitted electromagnetic wave, the reflected electromagnetic wave reflected by another doped surface and transmitted by another transmitter, thereby reducing a quantity of the receivers. Specifically, as shown in FIG. 9, the receiver 11 that is originally configured to receive the electromagnetic wave transmitted by the transmitter 10 and passing through the to-be-detected material S also receives the electromagnetic wave transmitted by the transmitter 20 and reflected by the second doped surface (the lower doped surface). The receiver 21 that is originally configured to receive the electromagnetic wave transmitted by the transmitter 20 and passing through the to-be-detected material S also receives the electromagnetic wave transmitted by the transmitter 10 and reflected by the first doped surface (the upper doped surface), thereby reducing a quantity of receivers, saving costs, and facilitating installation.

It should be noted that, when the to-be-detected material with two sides doped is detected, especially when the first optical module is added to make one receiver simultaneously receive the reflected electromagnetic wave of a same side and a transmitted electromagnetic wave of the other side, in order to avoid mutual influence of measurement of the two doped surfaces, the two transmitters may work at different times (time division mode), that is, the two transmitters transmit the measurement electromagnetic wave at different moments, or the two transmitters work at a same time, but at different carrier frequencies (frequency division mode), and both the two receivers can detect a frequency of a received signal. An architecture of the two receivers may adopt a superhererodyne or a zero intermediate frequency coherent receiver architecture, thereby avoiding mutual influence of electrical characteristics detection of the two doped surfaces.

Further, for the to-be-detected material doped on two sides, in order to save space and reduce installation difficulty of the detection apparatus, the embodiment of the present disclosure further provides a detection apparatus, including an electromagnetic wave transceiver module. The electromagnetic wave transceiver module is configured to transmit a measurement electromagnetic wave to a first doped surface and a second doped surface of the to-be-detected material, and receive a third electromagnetic wave and a fourth electromagnetic wave. The third electromagnetic wave includes the measurement electromagnetic wave reflected from the first doped surface and the second doped surface of the to-be-detected material, and the fourth electromagnetic wave includes the measurement electromagnetic wave transmitting through the to-be-detected material. The electromagnetic wave transceiver module is further configured to obtain the electrical characteristic parameters of the first doped surface and the second doped surface of the to-be-detected material and the electrical characteristic parameter of the body of the to-be-detected material based on the third electromagnetic wave and the fourth electromagnetic wave.

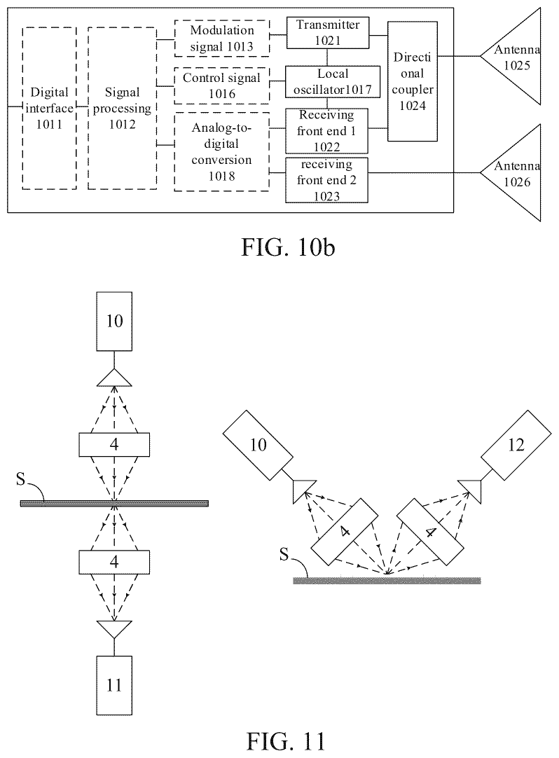

FIG. 10a is a schematic structural diagram of a transceiver integrated detection module according to an embodiment of the present disclosure. FIG. 10b is a schematic structural diagram of a transceiver integrated detection module according to another embodiment of the present disclosure. As shown in FIG. 10a and FIG. 10b, the transceiver module is the transceiver modules. The transceiver module may include a module of one transmission and one receiver in an upper part of FIG. 10a, a module of one transmission and multiple receivers in a lower part of FIG. 10a, and a module of one transmission and multiple receivers in FIG. 10b. The module of one transmission and one receiver may be a module for implementing a function of transmitting the electromagnetic wave and receiving the electromagnetic wave, and the module of one transmission and multiple receivers may be a module for implementing a function of transmitting the electromagnetic wave and a function of identifying and receiving multiple electromagnetic waves. The module of one transmission and one receiver may further cooperate with another receiver to detect the electrical characteristic of the to-be-detected material with the two sides doped. For the module of one transmission and multiple receivers, it only needs to dispose the two transceiver modules on two sides of the to-be-detected material, so that the electrical characteristics of the two doped surfaces and the body of the to-be-detected material may be detected, thereby greatly reducing an installation space.

Specifically, for the transceiver module of one transmission and one receiver, hardware of the transceiver module includes an antenna 1020, an isolator 1015, a transmitter 1014 and a receiving front end 1019, so as to implement a function of transmitting and receiving the electromagnetic wave. For the transceiver module of one transmission and multiple receivers shown in FIG. 10a, hardware of the transceiver module includes an antenna 1025, a directional coupler 1024, a transmitter 1021 and a plurality of receiving front ends (that is, a receiving front end 11022 and a receiving front end 21023), so as to implement a function of transmitting, identifying and receiving multiple electromagnetic waves. For the transceiver module of one transmission and multiple receivers shown in FIG. 10b, hardware of the transceiver module includes an antenna 1025, an antenna 1026, a directional coupler 1024, a transmitter 1021 and a plurality of receiving front ends (that is, a receiving front end 11022 and a receiving front end 21023), so as to implement a function of transmitting, identifying and receiving multiple electromagnetic waves. The receiving front end 11022 is configured to detect the amplitude and the phase of an output signal of the transmitter 1021, and the receiving front end 21023 is configured to measure a reflected wave received by the antenna 1026, for example, in the embodiment illustrated in FIG. 4. A basic circuit module is included in each of the foregoing three transceiver modules and includes a digital interface 1011, a circuit of signal processing 1012, a circuit of modulation signal 1013, a circuit of control signal 1016, a circuit of analog-to-digital conversion 1018 and a circuit of local oscillator 1017, so as to implement basic functions such as signal transmission, signal processing and analog-to-digital conversion.

It should be noted that, when the transceiver module detects the to-be-detected material with two sides doped, because the module has both functions of transmitting and receiving electromagnetic waves, fewer apparatuses may be provided on any side of the to-be-detected material to save space. However, in this case, the surfaces on the two sides may interfere with each other. Therefore, same as the embodiments in which the to-be-detected material with two sides doped is detected, different transceiver modules operate in a time division mode or frequency division mode, thereby avoiding detection interference and improving detection accuracy.

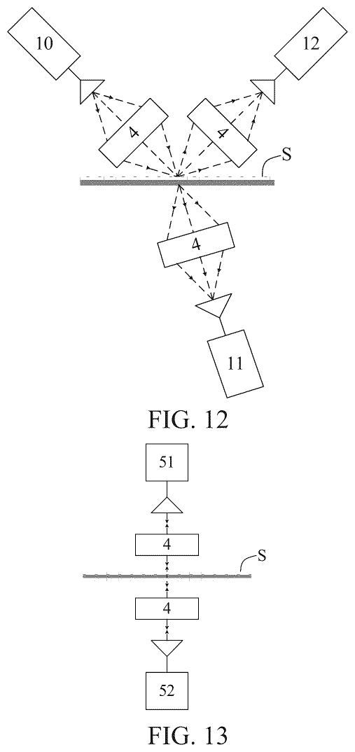

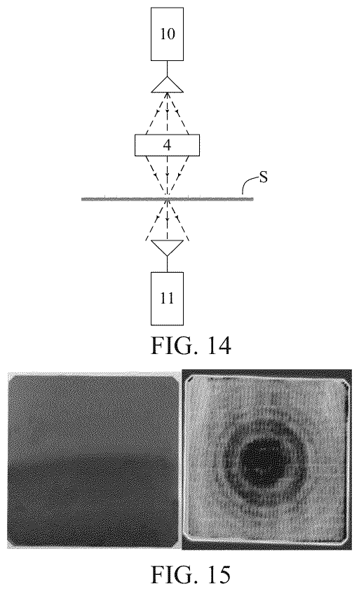

On the basis of the foregoing embodiments, the detection apparatus provided in the present disclosure may further include a second optical module. FIG. 11 to FIG. 14 are schematic diagrams of a detection apparatus including a second optical module according to an embodiment of the present disclosure.

Specifically, as shown in FIG. 11 to FIG. 14, the second optical module may be a set of transmission mirrors or reflection mirrors. On the basis of the foregoing embodiments, for various implementations of separate transmission, separate reflection and a combination of a transmission and a reflection, and in the embodiments in which the transmitter and the receiver are integrated, the set of transmission mirrors or reflection mirrors 4 may be added at the transmitter, the receiver, or at both ends of the transmitter and the receiver. As shown in FIG. 11 to FIG. 14, the set of transmission mirrors or reflection mirrors 4 is disposed on one or two sides of the to-be-detected material to focus the electromagnetic wave, so that the electrical characteristic of the to-be-detected material is measured in a smaller area by using the electromagnetic wave, thereby improving detection accuracy. Moreover, strength of a signal received by the receiver may be greatly enhanced, and the signal-to-noise ratio of the detection system may be improved.

The second optical module may use a set of transmission mirrors or reflection mirrors in various shapes, for example, an ellipse shape. A form of the set of transmission mirrors or reflection mirrors includes a combination of one or more spherical and aspherical transmission mirrors or spherical and aspherical reflection mirrors. A material of the transmission mirror may be glass, polytetrafluoroethylene (PTFE) or another dielectric material with small attenuation to terahertz waves, and a material of the reflection mirror may be metal or any material coated with metal or other conductive materials.

It should be noted that referring to FIG. 11, an optical path angle of a measurement electromagnetic wave (that is, the terahertz wave) transmitted by a transmitter 10 may have a slope (that is, a tilt angle) with the to-be-detected material on a production line, so as to avoid standing wave interference caused by reflections in a plurality of times. Moreover, in the embodiment of the present disclosure, the terahertz wave is focused on the to-be-detected material S (for example, a silicon wafer) by the set of transmission mirrors or reflection mirrors 4. However, in some scenarios, a parallel terahertz wave (also referred to as collimated beam extension light) may also be formed by the set of transmission mirrors or reflection mirrors 4. That is, both the terahertz focusing wave and the collimated beam extension light are implemented by using a transmission mirror or a reflection mirror.

Further, based on the foregoing detection of the electrical characteristic of the to-be-detected area of the to-be-detected material, the detection apparatus provided in the embodiment of the present disclosure may further includes a transmission apparatus, or an external transmission apparatus is used. The transmission apparatus is configured to move the to-be-detected material or the detection apparatus, or move both the to-be-detected material and the detection apparatus, so that the detection apparatus may detect the electrical characteristic parameters of the doped surfaces and the body of different areas of the to-be-detected material, and the electrical characteristic distribution detection of the to-be-detected material is realized.

That the to-be-detected material is a silicon wafer is used as an example. It is assumed that, in an ideal case in which the silicon wafer material is uniformly distributed, electromagnetic wave imaging may display an image with same gray scale at all positions. However, the actual distribution of the silicon wafer material is not completely uniform, and the distribution diagram of different resistivity is formed in the process of pulling the silicon wafer rod. The left part of FIG. 15 is a silicon wafer in a normal optical vision, and the right part of FIG. 15 is imaging on electrical characteristic distribution after the electromagnetic wave irradiation and reception. Specifically, as shown in FIG. 15, in the present disclosure, on the basis of the foregoing embodiments, the to-be-detected material is moved, and electrical characteristics of different positions of the to-be-detected material are imaged and calculated by the detection apparatus, so that the electrical characteristic distribution of the to-be-detected material may be visualized, which has an important significance of quality detection.

Specifically, on the basis of the foregoing embodiments, the to-be-detected material may be successively moved in an X direction and a Y direction by the transmission apparatus such as a driving belt, so that the to-be-detected area is continuously changed, and the electrical characteristic detection of the entire to-be-detected material is completed to obtain the electrical characteristic distribution of the to-be-detected material. Alternatively, the to-be-detected material may be installed in a system of a driving belt to implement fast detection in a production line.

Further, in order to implement a high-speed detection of an electrical characteristic of the entire to-be-detected material, in some other embodiments of the present disclosure, the transmitting module may include a plurality of transmitters arranged in an array; and the receiving and processing module may include a plurality of receivers arranged in an array, where the array includes a line array and a plane array.

First, line scanning detection is performed by a line array. FIG. 16 is a schematic diagram of a line array detection apparatus according to an embodiment of the present disclosure. Figures in FIG. 16 respectively show that: the body of the to-be-detected material S without doping is detected by the transmitter array 60 composed of M transmitters and the receiver array 61 composed of N receivers; the doped surface of the to-be-detected material S with an upper surface doped is detected by the transmitter array 60 composed of M transmitters and the receiver array 61 composed of N receivers; the body and the doped surface of the to-be-detected material S with the upper surface doped are simultaneously detected by the transmitter array 60 composed of M transmitters, the receiver array 61 composed of N receivers and a receiver array 62 composed of N receivers; and the body and the doped surface of the to-be-detected material S with two surfaces doped are detected by a transceiver module array 63 composed of M transceiver modules.

Specifically, the to-be-detected material S, such as the silicon wafer, may be moved in a direction R perpendicular to the line array by mean of the transmission apparatus, for example, moved on a production line by using a drive belt. A length of a receiver array of a line array detection apparatus may be a size greater than a size of a tested silicon wafer, thereby implementing imaging of full coverage. Every receiver array may generate a separate image, so that a structure of transmission plus reflection may generate two images for a same tested silicon wafer, the two images carry different information, each pixel of a transmission imaging represents an attenuation value of the electromagnetic wave at a corresponding position of the tested silicon wafer, and each pixel of a reflection imaging represents a reflection loss value. From these attenuation and reflection loss images, a resistivity distribution diagram of a substrate and a surface of the silicon wafer may be obtained through calculation, thereby implementing efficient detection of electrical characteristic distribution of the entire silicon wafer.

It should be noted that, when the line scanning detection is performed by using the line array detection apparatus, a quantity of pixels along a direction of the array depends on a quantity N of the receivers in a receiver array, and a minimum value of a quantity M of the transmitters in a transmitter array may be 1, and the maximum value of the quantity M is not limited, and a value of the quantity M may be adaptively changed according to an actual requirement. For example, when M=N (in this case, a cost of a single transmitter is usually low or an output signal strength is low), each receiver in the receiver array corresponds to one transmitter in the transmitter array. Another typical structure is M=1, that is, there is only one transmitter in the transmitter array, and the electromagnetic wave transmitted by the transmitter is received by a receiver in all receiver arrays (this is usually a case in which a single transmitter is in high cost or an output signal strength is high). The set of transmission mirrors or reflection mirrors may be used, so that an emission wave of a single transmitter is focused on the silicon wafer to form a linear “spot” that “lights” an imaging area of the receiver array.

On the basis of the foregoing embodiments of the present disclosure, the transmitter, the receiver, or the transceiver module may be any combination of M and N, and the set of transmission mirrors or reflection mirrors may be disposed on any side of the to-be-detected material. FIG. 17 is a schematic diagram of a line array detection apparatus combined with a transmission mirror according to an embodiment of the present disclosure. The left part of FIG. 17 is a detection apparatus combined with a one-side transmission mirror, and the right part of FIG. 17 is a detection apparatus combined with two-side transmission mirrors. As shown in FIG. 17, the set of transmission mirrors or reflection mirrors 4 may be disposed on a side of a transmitter array 60, or on both a side of the transmitter array 60 and a side of a receiver array 61, so as to focus the electromagnetic wave and improve detection efficiency of the line array detection apparatus.

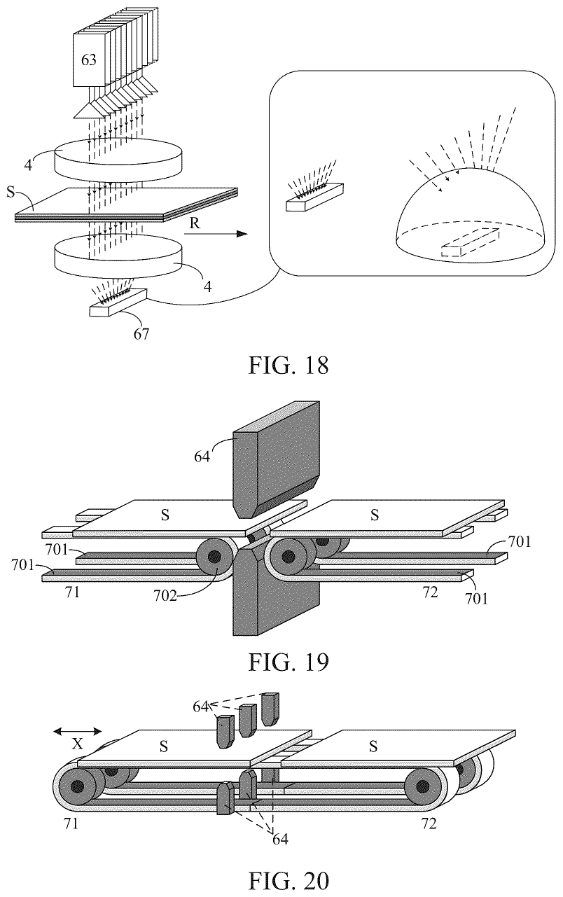

In addition, in the foregoing embodiments, a plurality of independent receivers are arranged at equal intervals to form the receiver array, and a total arrangement length thereof exceeds a size of the to-be-detected material, such as a silicon wafer, so as to cover the scanning imaging of the entire silicon wafer. A center-to-center spacing between two adjacent receivers is equal to a physical spacing represented by each imaging pixel point (that is, equal-scale imaging). In some other embodiments of the present disclosure, the receiver array may further be integrated into one chip, so as to improve a density (that is, a quantity of pixel points) of integrated channels. However, since a size of the chip is relatively small, and the effect corresponding to the transmitter array is not good, and therefore, the set of transmission mirrors or reflection mirrors may be combined to reduce imaging. The part in a dotted line frame on the right side of FIG. 18 shows two manners of receiving electromagnetic wave of a receiver array chip 67, where a dotted line with an arrow represents an irradiated electromagnetic wave. As shown in the part in a dotted line frame in FIG. 18, the receiver array chip 67 may directly receive the electromagnetic wave, or may receive a measurement electromagnetic wave by enhancing directivity of a received spatial signal by means of a dielectric transmission mirror (for example, a hemispheric or a super hemispheric silicon transmission mirror) irradiated backwards.

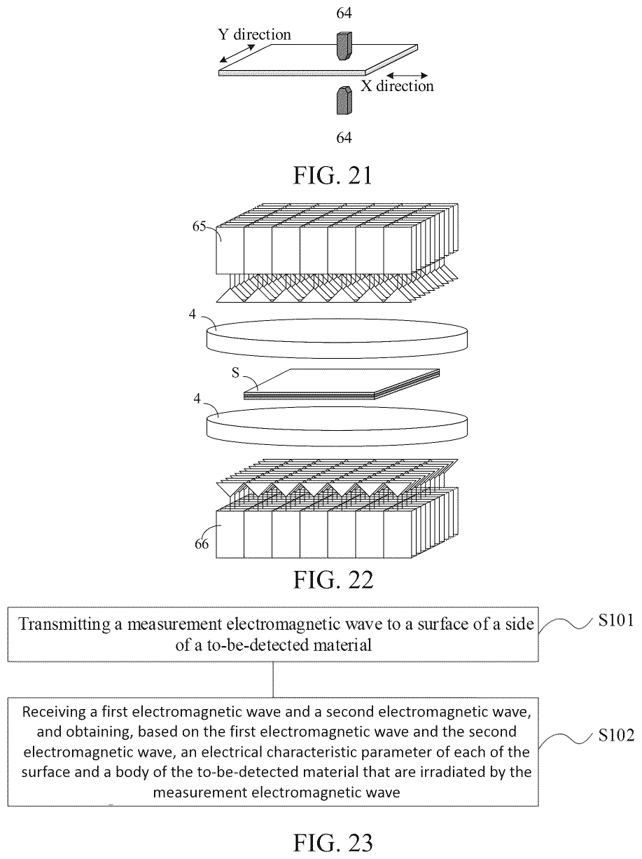

The following describes in detail a working principle of the line array detection apparatus provided in the present disclosure by using a complete embodiment. As shown in FIG. 19, FIG. 20, and FIG. 21, in the embodiments of the present disclosure, a production line transmission belt may be used as a transmission apparatus to move the to-be-detected material such as a silicon wafer. The transceiver module array is used as an example, as shown in FIG. 19, a transceiver module array 64 may be installed in a gap between two independent drive belts 71 and 72, where reference sign 701 indicates a rubber strip, reference sign 702 indicates a roller, and the transceiver module array 64 may be installed between drive belt rollers at two ends. To reduce costs, a line array detection apparatus with a relatively small array size M and N may be used, for example, M=N=3, as shown in FIG. 20, the transmitter array, the receiver array and the transceiver module array in the line array detection apparatus may be separately placed, and are interleaved between different rubber strips of the drive belt to implement detection on three tracks; alternatively, when M=N=1, as shown in FIG. 21, single point detection is implemented, or two-dimensional detection is implemented with reference to a mechanical motion of X and Y. In this way, the entire to-be-detected material may be detected by using the drive belt of the production line, and full detection of the production line is implemented on a basis of minimizing a change of an original generation line, thereby greatly improving practicality of the detection apparatus and the detection efficiency.

Further, in some other embodiments of the present disclosure, the detection apparatus may further be a surface array detection apparatus. As shown in FIG. 22, an array on any side may be used for transmitting or receiving, or the transceiver module may be used for transmissive detection, reflective detection, or both transmission and reflection. For example, as shown in FIG. 22, a detection array size is the transceiver module array 65 of X×Y and the transceiver module array 66 of M×N, where M, N, X and Y are integers greater than or equal to 1, and M×N may be equal to or not equal to X×Y. When a scanning area of a surface scanning array may cover the entire silicon wafer, when the one to-be-detected material is detected, only the to-be-detected material needs to be placed or moved to the detection area, and the silicon wafer or the detection apparatus does not need to be moved in the detection process, thereby greatly improving the detection efficiency.

In addition, the set of transmission mirrors or reflection mirrors may be added according to an actual requirement, and the signal energy of the transmitter array is distributed to a plane of the silicon wafer by the set of transmission mirrors or reflection mirrors, thereby improving a detection accuracy.

In an embodiment, the transmitting module includes a transmitter, the receiving and processing module includes a receiver and a processor, and the receiver is connected to the processor, or the processor is integrated into the receiver. The electromagnetic wave transceiver module includes a transceiver, and the transceiver includes a transmitter, a receiver and a processor, where the receiver is connected to the processor, or the processor is integrated into the receiver.

Specifically, the receiving and processing module may be a module formed by the receiver (namely, the electromagnetic wave receiver) and the processor connected to the receiver, that is, a form of a receiver external processor. The processor is configured to perform calculation based on data received by the receiver, to obtain an electrical characteristic parameter of a surface of the to-be-detected material and an electrical characteristic parameter of the body of the to-be-detected material, and the processor may be, for example, a processing chip. Alternatively, the receiving and processing module may be an electromagnetic wave receiver formed by integrating the processor in the receiver, and the receiving and processing module and the processor are not specifically limited in the embodiments of the present disclosure.

The electromagnetic wave transceiver module may be the transceiver (namely, the transceiver module). The electromagnetic wave transceiver may include the transmitter, the receiver and the processor connected to the receiver. Alternatively, the electromagnetic wave transceiver may include the transmitter and the receiver that integrates the processor in the receiver, and the electromagnetic wave transceiver module is not specifically limited in the embodiments of the present disclosure.

### Example Method

Based on a same concept of disclosure, the present disclosure further provides a detection method. FIG. 23 is a schematic flowchart of a detection method according to an embodiment of the present disclosure. As shown in FIG. 23, the detection method provided in this embodiment of the present disclosure is executed by the foregoing detection apparatus, and the method includes the following steps:

S101: transmitting a measurement electromagnetic wave to a surface of a side of a to-be-detected material.

S102: receiving a first electromagnetic wave and a second electromagnetic wave, and obtaining, based on the first electromagnetic wave and the second electromagnetic wave, an electrical characteristic parameter of the surface of the to-be-detected material and/or an electrical characteristic parameter of the body of the to-be-detected material.

The first electromagnetic wave includes the measurement electromagnetic wave reflected by the surface of the to-be-detected material, and the second electromagnetic wave includes the measurement electromagnetic wave transmitting through the to-be-detected material.

In addition to the foregoing methods and apparatuses, the embodiment of the present disclosure may further be a computer program product, and the computer program product includes a computer program instruction. The computer program instruction causes the processor to perform the steps in the image processing method described in various embodiments of the present disclosure described in the “exemplary method” section above in the processor when the processor is running.

The computer program product may write, in any combination of one or more program design languages, program code used to perform operations in an embodiment of the present disclosure, the program design language includes an object-oriented program design language, such as Java, C++, and further includes a conventional procedural program design language, such as “C” or a similar program design language. Program code may be executed completely on a user computing device, partly on the user equipment, as an independent package, partly on the user computing device, partly on a remote computing device or completely on the remote computing device or server.

In addition, an embodiment of the present disclosure may further be a computer readable storage medium, and a computer program instruction is stored on the computer readable storage medium. The computer program instruction causes a processor to perform the steps in the detection method according to various embodiments of the present disclosure described in the “exemplary method” section above when the processor is running.

The computer readable storage medium may use one or more arbitrary combination of readable media. The readable medium may be a readable signal medium or a readable storage medium. The readable storage medium may include, for example, but is not limited to, an electrical, magnetic, optical, electromagnetic, infrared, or semiconductor system, device, or component, or any combination thereof. A more specific example (non-exhaustive list) of the readable storage medium includes: an electrical connection with one or more leads, a portable disk, a hard disk, a random-access memory (RAM), a read-only memory (ROM), an erasable programmable read-only memory (EPROM or flash memory), an optical fiber, a portable compact disk read-only memory (CD-ROM), an optical storage device, a magnetic storage device, or any suitable combination of the foregoing.

The foregoing description has been given for a purpose of illustration and description. In addition, the description is not intended to limit embodiments of the present disclosure to a form disclosed herein. Although several example aspects and embodiments have been discussed above, those skilled in the art will recognize some of their variations, modifications, changes, additions, and sub-combinations.

### Industrial Applicability

According to the detection apparatus provided by the embodiments of the present disclosure, the detection apparatus includes a transmitting module and a receiving and processing module, the transmitting module is configured to transmit a measurement electromagnetic wave to a surface of a side of a to-be-detected material; and the receiving and processing module is configured to receive a first electromagnetic wave and a second electromagnetic wave, and obtain, based on the first electromagnetic wave and the second electromagnetic wave, an electrical characteristic parameter of the surface and/or a body of the to-be-detected material that are irradiated by the measurement electromagnetic wave, where the first electromagnetic wave includes the measurement electromagnetic wave reflected from the surface of the to-be-detected material, and the second electromagnetic wave includes the measurement electromagnetic wave transmitting through the to-be-detected material. In this way, by transmitting the electromagnetic wave to the to-be-detected material, and by receiving the reflected and transmitted electromagnetic wave, the electrical characteristic parameter of the surface of the to-be-detected material and the electrical characteristic parameter of the body of the to-be-detected material may be obtained according to a receiving result of the electromagnetic wave and an electromagnetic wave attenuation principle, so that a nondestructive detection is realized, and the electrical characteristic parameter of the surface of the to-be-detected material and the electrical characteristic parameter of the body of the to-be-detected material may be detected by transmitting an electromagnetic wave once, thereby greatly improving a detection effect.

1. A detection apparatus, comprising:
a transmitting module, configured to transmit a measurement electromagnetic wave to a surface of a side of a to-be-detected material; and
a receiving and processing module, configured to receive a first electromagnetic wave and a second electromagnetic wave, and obtain, based on the first electromagnetic wave and the second electromagnetic wave, an electrical characteristic parameter of the surface and/or a body of the to-be-detected material that are irradiated by the measurement electromagnetic wave,
wherein the first electromagnetic wave comprises the measurement electromagnetic wave reflected from the surface of the to-be-detected material, and the second electromagnetic wave comprises the measurement electromagnetic wave transmitting through the to-be-detected material.

2. The detection apparatus according to claim 1, wherein the to-be-detected material comprises at least one doped surface of the to-be-detected material;
the transmitting module is configured to transmit the measurement electromagnetic wave to the doped surface of the to-be-detected material;
the first electromagnetic wave comprises at least one reflected electromagnetic wave, the second electromagnetic wave comprises at least one transmitted electromagnetic wave, the reflected electromagnetic wave comprises the measurement electromagnetic wave reflected from the doped surface of the to-be-detected material, and the transmitted electromagnetic wave comprises the measurement electromagnetic wave transmitting through the doped surface of the to-be-detected material; and
the receiving and processing module is configured to receive the reflected electromagnetic wave and the transmitted electromagnetic wave, and obtain, based on the reflected electromagnetic wave, an electrical characteristic parameter of the doped surface of the to-be-detected material, and obtain, based on the transmitted electromagnetic wave and the electrical characteristic parameter of the doped surface of the to-be-detected material, the electrical characteristic parameter of the body of the to-be-detected material.

3. The detection apparatus according to claim 2, wherein the receiving and processing module is configured to obtain an electrical characteristic image of the doped surface of the to-be-detected material based on the reflected electromagnetic wave, and calculate the electrical characteristic parameter of the doped surface of the to-be-detected material based on a pixel grayscale value of the electrical characteristic image; and
the receiving and processing module is further configured to calculate an intermediate parameter based on the transmitted electromagnetic wave, and use a difference between the intermediate parameter and the electrical characteristic parameter of the doped surface of the to-be-detected material as the electrical characteristic parameter of the body of the to-be-detected material.

4. The detection apparatus according to claim 2, wherein the to-be-detected material comprises a first doped surface and a second doped surface, and the first doped surface and the second doped surface are two opposite surfaces of the to-be-detected material;
the first electromagnetic wave comprises a first reflected electromagnetic wave and a second reflected electromagnetic wave; the first reflected electromagnetic wave is the measurement electromagnetic wave reflected from the first doped surface, and the second reflected electromagnetic wave is the measurement electromagnetic wave reflected from the second doped surface; and
the receiving and processing module is configured to obtain an electrical characteristic parameter of the first doped surface based on the first reflected electromagnetic wave, obtain an electrical characteristic parameter of the second doped surface based on the second reflected electromagnetic wave, and obtain the electrical characteristic parameter of the body of the to-be-detected material based on the transmitted electromagnetic wave, the electrical characteristic parameter of the first doped surface and the electrical characteristic parameter of the second doped surface.

5. The detection apparatus according to claim 1, further comprising: a first optical module, wherein the first optical module is configured to adjust an emission angle, a reflection angle and a transmission angle of the measurement electromagnetic wave.

6. The detection apparatus according to claim 1, wherein the transmitting module comprises a plurality of transmitters arranged in an array; and the receiving and processing module comprises a plurality of receivers arranged in an array.

7. The detection apparatus according to claim 6, wherein the plurality of receivers are arranged in an M×N array, and the plurality of transmitters are arranged in a X×Y array, M, N, X and Y are integers greater than or equal to 1, and M×N is equal to X×Y, or M×N is not equal to X×Y.

8. The detection apparatus according to claim 1, further comprising: a second optical module, wherein the second optical module is configured to focus the measurement electromagnetic wave, the first electromagnetic wave and the second electromagnetic wave.

9. The detection apparatus according to claim 1, further comprising: an excitation light source, wherein the excitation light source is configured to focus on a measurement region of the to-be-detected material, and excite the to-be-detected material to detect the electrical characteristic parameter of the body of the to-be-detected material.

10. The detection apparatus according to claim 9, wherein the electrical characteristic parameter of the body of the to-be-detected material comprises a carrier lifetime, and the excitation light source is configured to excite a carrier of the to-be-detected material to detect the carrier lifetime.

11. The detection apparatus according to claim 1, wherein the transmitting module comprises a first transmitter, the receiving and processing module comprises a first receiver and a second receiver, the first receiver is configured to receive the first electromagnetic wave, and the second receiver is configured to receive the second electromagnetic wave, and
the receiving and processing module is configured to obtain the electrical characteristic parameter of the body of the to-be-detected material based on the first electromagnetic wave and the second electromagnetic wave, and obtain a type of the to-be-detected material based on the electrical characteristic parameter of the body of the to-be-detected material.

12. The detection apparatus according to claim 1, wherein the transmitting module comprises a transmitter, the receiving and processing module comprises a receiver and a processor, and the receiver is connected to the processor, or the processor is integrated into the receiver.

13. A detection apparatus, comprising: an electromagnetic wave transceiver module,
wherein the electromagnetic wave transceiver module is configured to transmit a measurement electromagnetic wave to a first doped surface and a second doped surface of a to-be-detected material, and receive a third electromagnetic wave and a fourth electromagnetic wave, wherein the third electromagnetic wave comprises the measurement electromagnetic wave reflected from the first doped surface and the second doped surface, and the fourth electromagnetic wave comprises the measurement electromagnetic wave transmitting through the to-be-detected material; and
the electromagnetic wave transceiver module is further configured to obtain electrical characteristic parameters of the first doped surface and the second doped surface of the to-be-detected material and an electrical characteristic parameter of the body of the to-be-detected material based on the third electromagnetic wave and the fourth electromagnetic wave.

14. The detection apparatus according to claim 13, wherein at least two electromagnetic wave transceiver modules are provided, and the at least two electromagnetic wave transceiver modules operate in a time division mode, or the at least two electromagnetic wave transceiver modules operate in a frequency division mode;
in a case of the time division mode, the at least two electromagnetic wave transceiver modules transmit and receive the measurement electromagnetic waves at different times; in the case of the frequency division mode, the at least two electromagnetic wave transceiver modules transmit and receive the measurement electromagnetic waves of different frequencies.

15. The detection apparatus according to claim 13, wherein the electromagnetic wave transceiver module comprises a transceiver, the transceiver comprises a transmitter, a receiver and a processor, and the receiver is connected to the processor, or the processor is integrated into the receiver.

16. A detection method, comprising:
transmitting a measurement electromagnetic wave to a surface of a side of a to-be-detected material; and
receiving a first electromagnetic wave and a second electromagnetic wave, and obtaining, based on the first electromagnetic wave and the second electromagnetic wave, an electrical characteristic parameter of the surface and/or a body of the to-be-detected material that are irradiated by the measurement electromagnetic wave,
wherein the first electromagnetic wave comprises the measurement electromagnetic wave reflected by the surface of the to-be-detected material, and the second electromagnetic wave comprises the measurement electromagnetic wave transmitting through the to-be-detected material.

17. The detection method according to claim 16, wherein the to-be-detected material comprises at least one doped surface of the to-be-detected material;
the transmitting a measurement electromagnetic wave to a surface of a side of a to-be-detected material, comprises:
transmitting the measurement electromagnetic wave to the doped surface of the to-be-detected material;
the first electromagnetic wave comprises at least one reflected electromagnetic wave, the second electromagnetic wave comprises at least one transmitted electromagnetic wave, the reflected electromagnetic wave comprises a first part of the measurement electromagnetic wave reflected from the doped surface of the to-be-detected material, and the transmitted electromagnetic wave comprises a second part of the measurement electromagnetic wave transmitting through the doped surface of the to-be-detected material; and
the receiving a first electromagnetic wave and a second electromagnetic wave, and obtaining, based on the first electromagnetic wave and the second electromagnetic wave, an electrical characteristic parameter of the surface and/or a body of the to-be-detected material that are irradiated by the measurement electromagnetic wave, comprises:
receiving the reflected electromagnetic wave and the transmitted electromagnetic wave, and obtaining, based on the reflected electromagnetic wave, an electrical characteristic parameter of the doped surface of the to-be-detected material, and obtaining, based on the transmitted electromagnetic wave and the electrical characteristic parameter of the doped surface of the to-be-detected material, the electrical characteristic parameter of the body of the to-be-detected material.

18. The detection method according to claim 17, wherein the method further comprises:
obtaining an electrical characteristic image of the doped surface of the to-be-detected material based on the reflected electromagnetic wave, and calculating the electrical characteristic parameter of the doped surface of the to-be-detected material based on a pixel grayscale value of the electrical characteristic image; and
calculating an intermediate parameter based on the transmitted electromagnetic wave, and using a difference between the intermediate parameter and the electrical characteristic parameter of the doped surface of the to-be-detected material as the electrical characteristic parameter of the body of the to-be-detected material.

19. The detection method according to claim 16, wherein the transmitting a measurement electromagnetic wave to a surface of a side of a to-be-detected material, comprises:
transmitting, by a transmitting module, the measurement electromagnetic wave to the surface of a side of the to-be-detected material, wherein the transmitting module comprises a transmitter.

20. The detection method according to claim 16, wherein the receiving a first electromagnetic wave and a second electromagnetic wave, and obtaining, based on the first electromagnetic wave and the second electromagnetic wave, an electrical characteristic parameter of the surface and/or a body of the to-be-detected material that are irradiated by the measurement electromagnetic wave, comprises:
receiving, by a receiving and processing module, the first electromagnetic wave and the second electromagnetic wave, and obtaining, by the receiving and processing module based on the first electromagnetic wave and the second electromagnetic wave, the electrical characteristic parameter of each of the surface and the body of the to-be-detected material that are irradiated by the measurement electromagnetic wave,
wherein the receiving and processing module comprises a receiver and a processor, and the receiver is connected to the processor, or the processor is integrated into the receiver.
